(19) United States
(12) Patent Application Publication
(10) Pub. No.: US 2026/0173816 A1
(43) Pub. Date: Jun. 18, 2026

(54) COMPRESSION JIG FOR SEMICONDUCTOR MANUFACTURING APPARATUS

(71) Applicant: Samsung Electronics Co., Ltd., Suwon-si (KR)

(72) Inventors: JITAE LEE, Suwon-si (KR); JUNGMO YANG, Suwon-si (KR); HYEJI WI, Suwon-si (KR); EULJIN PARK, Suwon-si (KR); JINUK PARK, Suwon-si (KR); YOUNG-TAE CHOI, Suwon-si (KR)

(21) Appl. No.: 19/423,003

(22) Filed: Dec. 17, 2025

(30) Foreign Application Priority Data
Dec. 17, 2024 (KR) 10-2024-0188031

(51) Int. Cl. H10P 72/76

(52) U.S. Cl. CPC H10P 72/7611

(57) ABSTRACT

A compression jig includes a cover part that covers a ceiling opening of a ceiling part of a chamber, compression columns that passes through the cover part, a compression ring that is connected to lower ends of the compression columns, a mechanical driving part that is provided on the cover part, and connected to the compression columns, and a venting part including a vent hole that passes through the cover part.

### CROSS-REFERENCE TO RELATED APPLICATION

This application claims priority under 35 U.S.C. § 119 to Korean Patent Application No. 10-2024-0188031 filed on Dec. 17, 2024, in the Korean Intellectual Property Office, the disclosure of which is incorporated by reference herein in its entirety.

### BACKGROUND

Various processes may be involved in the manufacture of a semiconductor device. For example, etching processes and film formation processes may be used. In some etching processes, such as dry etching, and in some film formation processes, such as sputtering and plasma-enhanced chemical vapor deposition, plasma processing may be used. Meanwhile, as semiconductor products become more miniaturized and highly integrated, it may be desirable for semiconductor manufacturing processes to exhibit uniform process characteristics.

### SUMMARY

In some examples, methods capable of reducing process variation during plasma treatment of a semiconductor substrate may be desired.

Implementations of the present disclosure provide a compression jig capable of suppressing or minimizing air bubbles between a thermal pad and a chuck.

In some aspects, the present disclosure provides a compression jig including a cover part that covers a ceiling opening of a ceiling part of a chamber, compression columns that passes through the cover part, a compression ring that is connected to lower ends of the compression columns, a mechanical driving part that is provided on the cover part, and connected to the compression columns, and a venting part including a vent hole that passes through the cover part.

In some implementations, the chamber may have an interior space, the compression ring may compress a focus ring provided on a periphery of a chuck in the chamber, and the cover part may seal the interior space in a vacuum state when a thermal pad provided on a lower surface of the focus ring and the periphery of the chuck are compressed by the compression ring.

In some implementations, the mechanical driving part may include a horizontal support that is connected to upper ends of the compression columns, and a vertical support that passes through a central portion of the horizontal support, and is provided at a central portion of an upper surface of the cover part, the horizontal support may be movable along a lengthwise direction of the vertical support, and the compression columns may be fixed to the horizontal support and are movable together with the horizontal support.

In some implementations, the mechanical driving part may further include a driver that is connected to an upper end of the vertical support and rotates the vertical support, and the horizontal support may be vertically movable in response to rotation of the vertical support.

In some implementations, the mechanical driving part may further include at least one driver provided between the horizontal support and the cover part, the driver may be vertically contractable and vertically expandable, and the horizontal support may be vertically movable in response to contraction or expansion of the driver.

In some implementations, the horizontal support may include arm portions radially extending from the central portion of the horizontal support, and the upper ends of the compression columns may be connected to the arm portions of the horizontal support, respectively.

In some implementations, the cover part may include a lower cover having an opening, and an upper cover that is provided on the lower cover and covers the opening, and the compression columns may pass through the upper cover and pass through the opening of the lower cover, and the vent hole may pass through the upper cover.

In some implementations, the cover part may have a recess that is formed within a periphery of a lower surface of the cover part and extends along the periphery of the cover part, and the compression jig may further include a first sealing member provided in the recess.

In some implementations, the compression jig may further include a guide part that is provided on the cover part and surrounds each of the compression columns, and a second sealing member that is provided between the guide part and the compression column.

In some implementations, the mechanical driving part may include a horizontal support that is connected to upper ends of the compression columns, and a variable support that is fixed to a lower surface of a central portion of the horizontal support and is provided at a central portion of an upper surface of the cover part, the variable support may be vertically contractable and vertically expandable, the compression columns may be fixed to the horizontal support and may be movable together with the horizontal support, and the horizontal support may be vertically movable in response to contraction or expansion of the variable support.

### BRIEF DESCRIPTION OF THE FIGURES

FIG. 1 is a cross-sectional view of an example of a semiconductor manufacturing apparatus.

FIG. 2 is a rear view illustrating an example of a focus ring and an example of a thermal pad.

FIG. 3 is an enlarged cross-sectional view of area F1 of FIG. 1.

FIG. 4 illustrates an example of a focus ring that has a different shape, and is an enlarged cross-sectional view corresponding to area F1 of FIG. 1.

FIG. 5 is a cross-sectional view of an example of a compression jig.

FIG. 6 is a plan view of an example of a horizontal support.

FIG. 7 is a rear view of an example of a compression ring.

FIGS. 8, 9, and 10 are cross-sectional views illustrating an operation method of an example of a compression jig.

FIG. 11 is an enlarged cross-sectional view of area F2 of FIG. 10.

FIG. 12 illustrates an example of a second sealing member that has a different shape, and is an enlarged cross-sectional view corresponding to area F2 of FIG. 10.

FIG. 13 is a cross-sectional view of an example of a compression jig.

FIG. 14 is an enlarged cross-sectional view of area F3 of FIG. 13.

FIG. 15 is a cross-sectional view of an example of a compression jig.

FIG. 16 is a cross-sectional view of an example of a compression jig.

FIG. 17 is a cross-sectional view of an example of a compression jig.

### DETAILED DESCRIPTION

Hereinafter, implementations of the present disclosure will be described clearly and in detail with reference to the accompanying drawings.

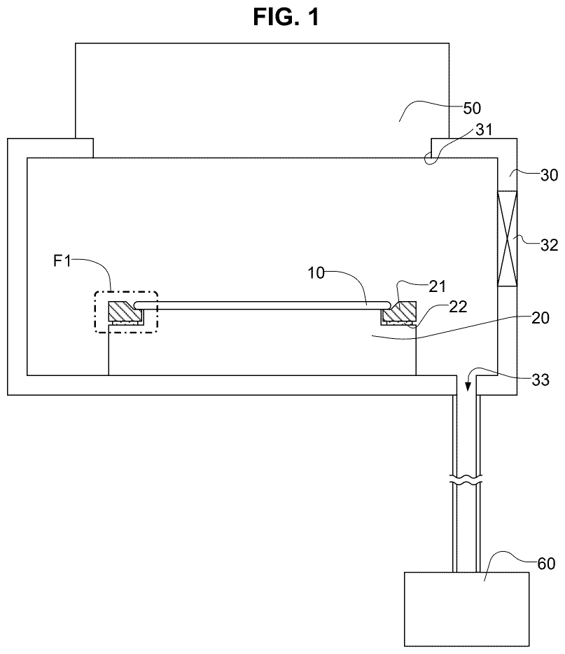

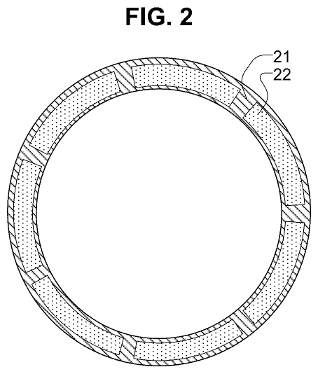

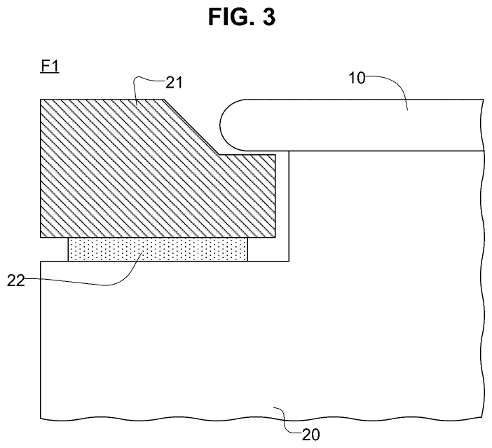

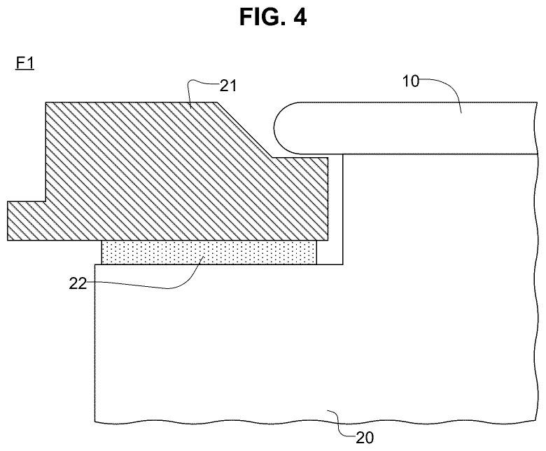

FIG. 1 is a schematic cross-sectional view of a semiconductor manufacturing apparatus according to some implementations of the present disclosure. FIG. 2 is a rear view illustrating a focus ring 21 and a thermal pad 22, which are mounted on a semiconductor manufacturing apparatus according to some implementations of the present disclosure. FIG. 3 is an enlarged cross-sectional view of area F1 of FIG. 1. FIG. 4 is for illustrating a focus ring 21 that has a different shape, and is an enlarged cross-sectional view corresponding to area F1 of FIG. 1.

Referring to FIG. 1, a semiconductor manufacturing apparatus according to some implementations of the present disclosure may include a chamber 30, a chuck 20, a vacuum source 60, and a top module 50. The chamber 30 may have an interior space, in which a semiconductor manufacturing process is performed. For example, the chamber 30 may include a bottom part, a wall part that extends upward from a periphery of the bottom part, and a ceiling part that overlaps the bottom part and is provided on the wall part. The interior space of the chamber 30 may be a space that is surrounded by the bottom part, the wall part, and the ceiling part of the chamber 30.

The chamber 30 may have a ceiling opening 31, a transfer port 32, and an exhaust port 33. The ceiling opening 31 may pass through the ceiling part of the chamber 30. The transfer port 32 may be provided in the wall part. The transfer port 32 may be opened and closed. The substrate 10 may enter and exit the chamber 30 through the transfer port 32. The exhaust port 33 may pass through the bottom part of the chamber 30. The exhaust port 33 may be connected to the vacuum source 60. In some implementations, although not illustrated, an additional pipe passage and an opening/closing device (not illustrated) may be disposed between the exhaust port 33 and the vacuum source 60. Installation positions of the transfer port 32 and the exhaust port 33 are not limited thereto, and in some implementations, they may be provided at different positions.

The chuck 20 may be disposed on the bottom part of the chamber 30. The chuck 20 may be an electrostatic chuck that fixes the substrate 10 to an upper portion of the chuck 20 by using electrostatic force. In some implementations, although not illustrated, a cooling passage may be provided in an interior of the chuck 20, and a coolant may flow through the cooling passage. A temperature of the chuck 20 may be controlled by the coolant. The coolant may include water or liquid helium, but the present disclosure is not limited thereto.

The top module 50 may be disposed on the chamber 30 to cover the ceiling opening 31 of the chamber 30. The semiconductor manufacturing apparatus according to some implementations of the present disclosure may be a plasma treating apparatus. For example, the plasma treating apparatus may be a plasma etching apparatus, a sputtering apparatus, or a plasma-enhanced chemical vapor deposition apparatus. However, the semiconductor manufacturing apparatus of the implementation is not limited thereto. When the semiconductor manufacturing apparatus according to some implementations of the present disclosure is a plasma treating apparatus, the top module 50 may include an upper electrode that is one of electrodes for generating plasma. The top module 50 may further include a gas inlet pipe passage (not illustrated) and a mass flow controller (not illustrated) for supplying a gas for generating plasma. In some implementations, although not illustrated, an insulator may be further provided between the top module 50 and the ceiling opening 31. The top module 50 may be demounted from the chamber 30 for maintenance of the semiconductor manufacturing apparatus.

When the semiconductor manufacturing apparatus according to some implementations of the present disclosure is a plasma treating apparatus, the chuck 20 may include a lower electrode. In some implementations, although not illustrated, an insulator may be disposed to surround a side surface of the chuck 20. In some implementations, although not illustrated, additional components may be further provided between the chuck 20 and the bottom part. A focus ring 21 may be disposed on a periphery of the chuck 20. A width of an upper end portion of the chuck 20 may be smaller than a width of a remaining portion of the chuck 20. Accordingly, the chuck 20 may have a step that is formed along a periphery of the upper end portion to be adjacent to the upper end portion. The focus ring 21 may be seated on the step. A thermal pad 22 may be disposed between an upper surface of the step and a lower surface of the focus ring 21. The thermal pad 22 may have tackiness or adhesiveness, so that the focus ring 21 may be coupled to the chuck 20 through the thermal pad 22. The thermal pad 22 may have thermal conductivity, so that it may function as a heat transfer path between components that contact the thermal pad 22. For example, when the focus ring 21 on the thermal pad 22 is exposed to a heat source and heated, heat of the focus ring 21 may be transferred to the chuck 20 through the thermal pad 22, so that the focus ring 21 may be cooled.

Referring to FIG. 2, the thermal pad 22 may include a plurality of pad pieces. The pad pieces may be disposed on a lower surface of the focus ring 21 to be spaced apart from each other in an extension direction of the focus ring 21. The number and/or arrangement interval of the pad pieces are not limited to those illustrated, and in some implementations, the number and/or arrangement interval of the pad pieces may vary. For example, the thermal pad 22 may be a single pad. The thermal pad 22 may, for example, include silicone, and a filler having a high thermal conductivity in the silicone. A material of the thermal pad 22 is not limited thereto. The focus ring 21 may be formed of silicon (Si) or silicon carbide (SiC). A material of the focus ring 21 is not limited thereto, and in some implementations, the focus ring 21 may include another material. For example, the focus ring 21 may include quartz, alumina, or boron carbide.

Referring to FIGS. 3 and 4, a width of the thermal pad 22 on a cross section may be smaller than a width of the focus ring 21. When the substrate 10 is loaded on the chuck 20, a periphery of the substrate 10 may overlap at least a portion of the step of the chuck 20. The focus ring 21 may be spaced apart from a lower surface of the periphery of the substrate 10. The lower surface of the periphery of the substrate 10 may not contact the focus ring 21, but may vertically overlap a portion of the focus ring 21. An upper surface of the focus ring 21 may include a first surface that is relatively close to the chuck 20, and a second surface that is relatively distant from the chuck 20. A level of the first surface of the focus ring 21 may be different from a level of the second surface of the focus ring 21. Due to a level difference between the first surface and the second surface, the upper surface of the focus ring 21 may further include an inclined surface that connects the first surface and the second surface. The inclined surface may be a planar surface. However, a cross-sectional shape of the inclined surface is not limited to that illustrated, and in some implementations, the cross-sectional shape of the inclined surface may vary. In some implementations, the level of the first surface may be lower than the level of the second surface. In some implementations, the level of the second surface may be substantially the same as a level of an upper surface of the loaded substrate 10. However, a relationship between the level of the second surface and the level of the upper surface of the substrate 10 is not limited thereto. In some implementations, the level of the second surface and the level of the upper surface of the substrate 10 may be different. In some implementations, the level of the second surface may be higher than the level of the upper surface of the substrate 10. The level of the first surface may be lower than a level of an uppermost surface (i.e., a surface that contacts the lower surface of the substrate 10) of the chuck 20. That is, the first surface may be spaced apart from the lower surface of the periphery of the substrate 10. However, the present disclosure is not limited thereto, and in some implementations, a vertical relationship of the levels of the first surface, the second surface, an upper surface of the substrate 10, and/or the uppermost surface of the chuck 20 may vary.

A step side surface that connects the step of the chuck 20 and the uppermost surface of the chuck 20 may be provided on the chuck 20. An inner surface of the focus ring 21 may be disposed to be spaced apart from the step side surface of the chuck 20. As illustrated in FIG. 3, an outer surface of the focus ring 21 may be substantially vertically aligned with an outer surface of the chuck 20. Unlike this, as illustrated in FIG. 4, the outer surface of the focus ring 21 may protrude laterally farther than the outer surface of the chuck 20. In this case, a protruding portion of the focus ring 21 may vertically overlap a portion of an additional component (not illustrated) that surrounds the chuck 20.

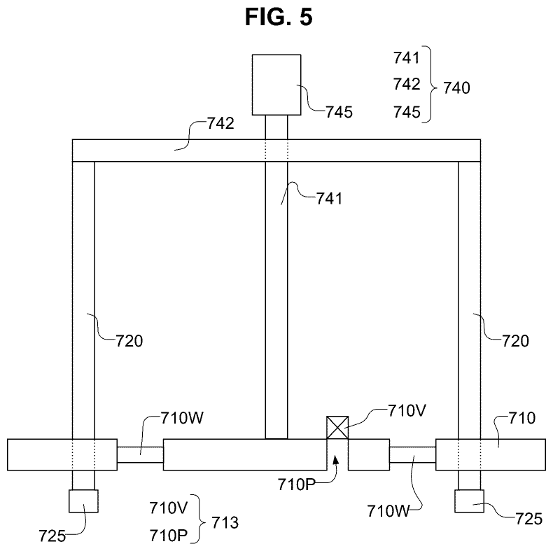

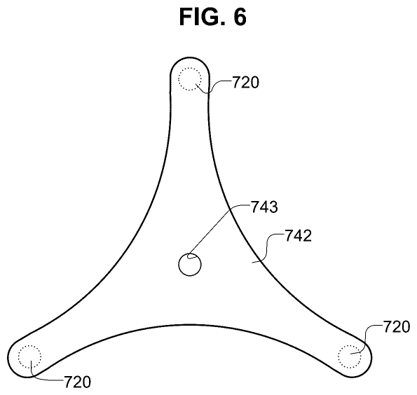

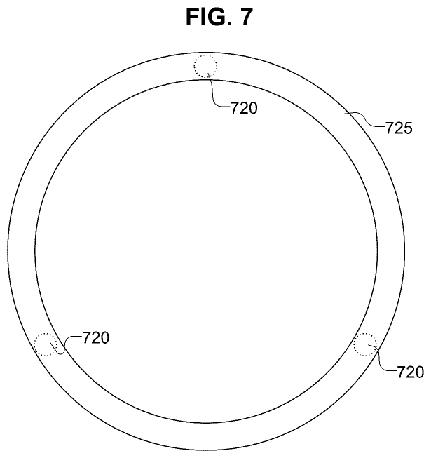

FIG. 5 is a cross-sectional view of a compression jig according to some implementations of the present disclosure. FIG. 6 is a plan view of a horizontal support according to some implementations of the present disclosure. FIG. 7 is a rear view of a compression ring according to some implementations of the present disclosure.

Referring to FIGS. 5, 6, and 7, a compression jig according to some implementations of the present disclosure may include a cover part 710, a compression column 720, a compression ring 725, a mechanical driving part 740, and a venting part 713. The mechanical driving part 740 may include a horizontal support 742, a vertical support 741, and a driver 745. The venting part 713 may include a vent hole 710P and an opening/closing device 710V. The horizontal support 742 may include a central portion and arm portions. The horizontal support 742 may have a through-hole 743 at the central portion. The cover part 710 may be configured to cover the ceiling opening 31 of the ceiling part of the chamber 30. The vent hole 710P may pass through the cover part 710. The opening/closing device 710V may be installed to be connected to the vent hole 710P. The opening/closing device 710V may open and close the vent hole 710P. The opening/closing device 710V may be, for example, a venting valve. At least one window 710W that is used to observe the interior of the chamber 30 may be installed in the cover part 710. An installation position of the window 710W is not limited to the illustrated position and may vary. In some implementations, the window 710W may be omitted. In some implementations, the window 710W may be formed of a polymer, quartz, or glass. The polymer may be, for example, polycarbonate. However, implementations of the present disclosure are not limited thereto, and various materials may be used for the window 710W.

A plurality of compression columns 720 may be provided. The plurality of compression columns 720 may be disposed to be spaced apart from each other horizontally. The compression columns 720 may pass through the cover part 710. The mechanical driving part 740 may be provided on the cover part 710. The compression columns 720 may be connected to the mechanical driving part 740. Lower ends of the compression columns 720 may be connected to the compression ring 725 provided below the cover part 710. The vertical support 741 may pass through the central portion of the horizontal support 742 through the through-hole 743 of the horizontal support 742. The vertical support 741 may be provided on a central portion of an upper surface of the cover part 710. The horizontal support 742 may be movable along a lengthwise direction of the vertical support 741. The compression columns 720 may be fixed to the horizontal support 742, and be movable together with the horizontal support 742. As illustrated in FIG. 6, the arm portions of the horizontal support 742 may be connected to the central portion and may extend radially from the central portion. The arm portions of the horizontal support 742 may be connected to upper ends of the compression columns 720. Lower ends of the compression columns 720 may be connected to an upper surface of the compression ring 725. When the horizontal support 742 is moved vertically, the compression ring 725 may also be moved vertically by the compression columns 720. A planar shape of the compression ring 725 may correspond to a planar shape of the focus ring 21. A lower surface of the compression ring 725 may be configured to contact at least a portion of an upper surface of the focus ring 21. A lower surface of the compression ring 725 may be configured to contact a second surface of the focus ring 21 during a compression operation. The compression ring 725 may be separable from the compression columns 720. Accordingly, when the focus ring has a different shape, a compression ring having a shape corresponding to the different shape of the focus ring may be mounted on lower ends of the compression columns 720. Although three compression columns 720 are illustrated in FIGS. 6 and 7, the number of the compression columns 720 is not limited thereto. Although the horizontal support 742 is illustrated as being radial in FIG. 6, a shape of the horizontal support 742 is not limited thereto, and in some implementations, the shape of the horizontal support 742 may vary. For example, when the number of the compression columns 720 is six, the horizontal support 742 may be hexagonal.

The driver 745 may be connected to an upper end of the vertical support 741 and may be configured to rotate the vertical support 741. The horizontal support 742 may be vertically movable in response to the rotation of the vertical support 741. For example, an inner wall of the through-hole 743 of the horizontal support 742 and the vertical support 741 may be coupled to each other by a ball screw method. In some implementations, the vertical support 741 may be rotated manually. For example, an operator may rotate the driver 745 and the vertical support 741 connected to the driver 745 by using a torque wrench. Unlike this, in some implementations, the vertical support 741 may be rotated semi-automatically. For example, the driver 745 may include components that convert pneumatic pressure of compressed air into rotational force, and may rotate the vertical support 741 by the rotational force. However, implementations of the present disclosure are not limited thereto, and various methods may be used for rotation of the vertical support 741.

In some implementations, the cover part 710, the vertical support 741, the horizontal support 742, the compression columns 720, and the compression ring 725 may be formed of a metal. For example, the metal may include aluminum. However, implementations of the present disclosure are not limited thereto, and various materials may be used for the cover part 710, the vertical support 741, the horizontal support 742, the compression columns 720, and the compression ring 725. The cover part 710, the vertical support 741, the horizontal support 742, the compression columns 720, and the compression ring 725 may be formed of different materials.

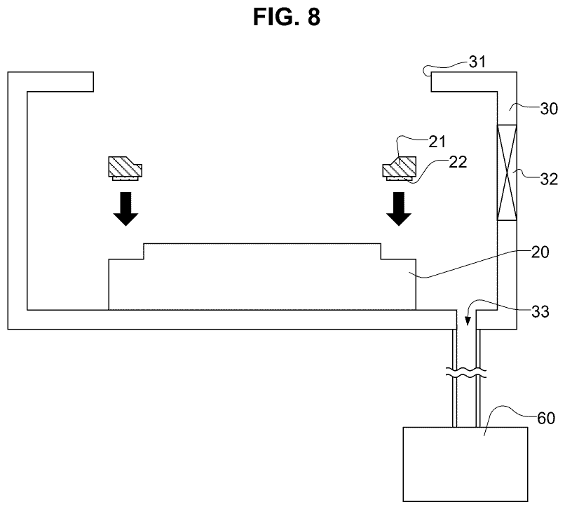

FIGS. 8, 9, and 10 are cross-sectional views illustrating an operation method of a compression jig according to some implementations of the present disclosure.

Referring to FIG. 8, in the semiconductor manufacturing apparatus of FIG. 1, the top module 50 may be demounted for maintenance. When the top module 50 is demounted, the ceiling opening 31 may be opened. Through the ceiling opening 31, a focus ring that needs to be replaced and a thermal pad coupled to the focus ring may be removed. Subsequently, a new focus ring 21 and a new thermal pad 22 may be disposed on a periphery (i.e., that is, a step of the chuck 20) of the chuck 20. The new thermal pad 22 (hereinafter, referred to as the thermal pad) may be coupled to a lower surface of the new focus ring 21 (hereinafter, referred to as the focus ring) outside the chamber 30. Thereafter, the thermal pad 22 and the focus ring 21 that are coupled to each other may be transferred into the chamber 30.

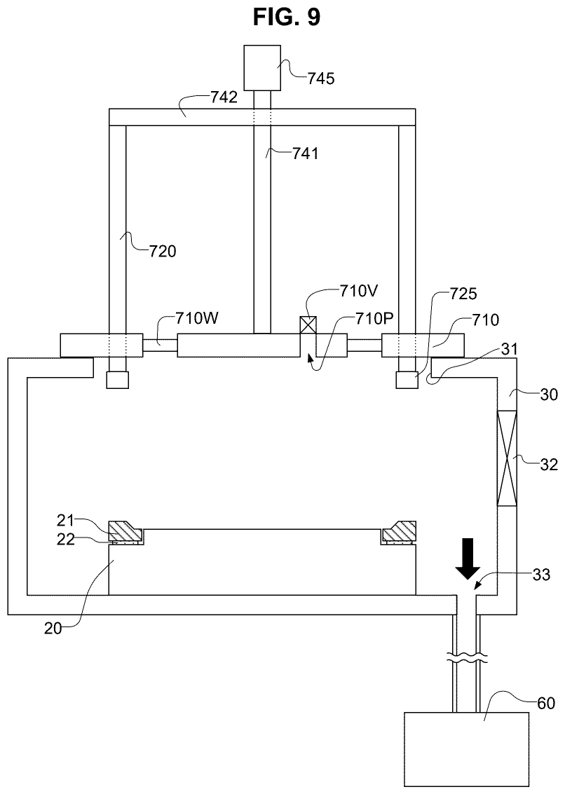

Referring to FIG. 9, the compression jig may be mounted on the ceiling opening 31. The cover part 710 of the compression jig may cover the ceiling opening 31, and the opening/closing device 710V may be closed. Accordingly, an interior space of the chamber 30 may be sealed. After the interior space is sealed, the interior space of the chamber 30 may be brought into a vacuum state having a certain degree of vacuum through the vacuum source 60. The certain degree of vacuum may be, for example, 1 mTorr or less. Air that is present in the interior space of the chamber 30 may be discharged through the exhaust port 33. While the interior space of the chamber 30 is being brought into a vacuum state, the compression jig may stand by with the compression ring 725 positioned adjacent to the ceiling opening 31.

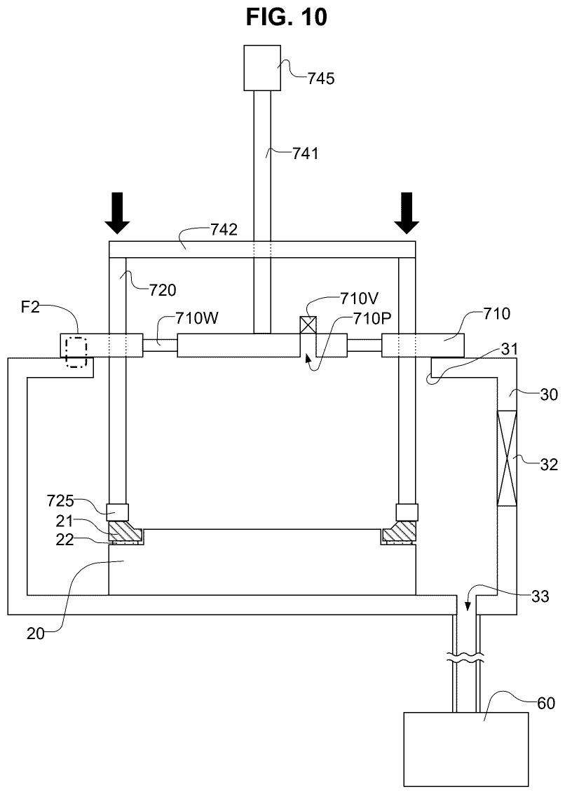

Referring to FIG. 10, while the interior space of the chamber 30 is in a vacuum state, the horizontal support 742 may descend vertically. The horizontal support 742 may descend in response to the rotation of the vertical support 741 due to the driver 745. As the horizontal support 742 descends, the compression columns 720 and the compression ring 725 may also descend. The descending compression ring may compress the focus ring 21 with a certain pressure. The certain pressure may be, for example, 5 kPa to 100 kPa. The certain pressure may be, for example, 12 kPa to 70 kPa. As described above, a pressure of the compression ring 725 may be controlled in response to movement of the horizontal support 742. Accordingly, an appropriate level of pressure that suppresses breakage of the focus ring 21 may be applied to the focus ring 21. By the pressure applied to the focus ring 21 through the compression ring 725, the thermal pad 22 attached to a lower surface of the focus ring 21 and the chuck 20 may be compressed. Because such compression is performed after the interior space of the chamber 30 is set to a vacuum state, inflow of air bubbles between a lower surface of the thermal pad 22 and a step surface of the chuck 20 may be minimized or prevented.

When air bubbles are introduced between the thermal pad 22 and the chuck 20, a level of an upper surface of the focus ring 21 may increase due to a volume of the air bubbles. In this case, during a subsequent plasma process, a height of a plasma sheath that is formed between the plasma and the substrate may locally vary, and thus, uniformity of the plasma process may be degraded and defects may occur. However, according to the above-described implementations of the present disclosure, because the compression jig performs compression after the interior of the chamber is set to a vacuum state, uniformity of the plasma process may be enhanced. Such enhancement in uniformity may be achieved by minimizing or preventing the occurrence of air bubbles.

When air bubbles are introduced between the thermal pad 22 and the chuck 20, heat transfer from the focus ring 21 to the chuck 20 may be hindered due to the low thermal conductivity of the air bubbles. In this case, during a subsequent plasma process, a local temperature of the focus ring 21 may become higher than a temperature of the substrate 10. When a local temperature of the focus ring 21 becomes higher than a temperature of the substrate 10, a by-product generated during a plasma treatment process may be deposited on a periphery of the substrate 10 instead of the focus ring 21, and thus, a uniformity of the plasma process may deteriorate and defects may occur. However, according to the above-described implementations of the present disclosure, because the compression jig performs compression after an interior of the chamber is set to a vacuum state, a uniformity of the plasma process may be enhanced. Such enhancement in uniformity may be achieved by minimizing or preventing the occurrence of air bubbles.

When compression of the thermal pad 22 and the focus ring 21 is completed, the compression ring 725 may ascend. Thereafter, venting may be performed to remove the compression jig. To perform venting, a pipe passage (not illustrated) connected to the vacuum source 60 may be closed by means, such as another opening/closing device (not illustrated) installed in the pipe passage, and the opening/closing device 710V may be opened. When the opening/closing device 710V is opened, exterior air may be introduced into an interior space of the chamber 30 through the vent hole 710P. Because the vent hole 710P is located at an upper portion of the chamber 30, a flow of the introduced exterior air may be directed from an upper side to a lower side in the chamber 30. Because a flow of the exterior air due to venting is a descending airflow, scattering of particles during the venting process may be suppressed or minimized.

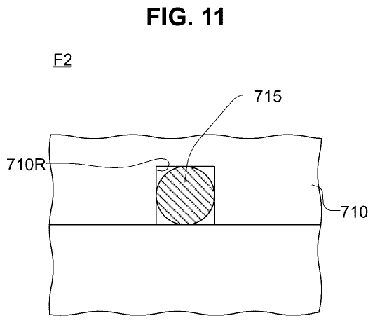

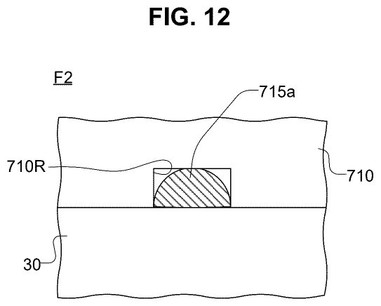

FIG. 11 is an enlarged cross-sectional view of area F2 of FIG. 10. FIG. 12 is for illustrating a second sealing member that has a different shape, and is an enlarged cross-sectional view corresponding to area F2 of FIG. 10.

Referring to FIGS. 11 and 12, the compression jig according to some implementations of the present disclosure may further include a sealing member. Such a sealing member may be provided inside a recess 710R that is formed within a periphery of a lower surface of the cover part 710 and extends along the periphery of the cover part 710. The sealing member provided in an interior of the recess 710R may be a first sealing member 715 illustrated in FIG. 11. The first sealing member 715 may be, for example, an O-ring having a circular or elliptical shape in a vertical cross section. When the first sealing member 715 is an O-ring having a vertical cross-sectional shape that is close to a circle, a vertical cross-sectional shape of the recess 710R may be close to a square. A shape of the first sealing member 715 is not limited thereto. For example, a vertical cross-sectional shape of the sealing member provided in the recess 710R may be close to a semicircle. In such a case, as illustrated in FIG. 12, the first sealing member 715a may be a D-ring. When the first sealing member 715a is a D-ring, a vertical cross-sectional shape of the recess 710R may be close to a rectangle. In addition to the O-ring and the D-ring described above, a component having another shape may be used as the first sealing member 715. Due to the sealing member provided in an interior of the recess 710R, a sealing performance for maintaining a vacuum between the compression jig and the ceiling part of the chamber 30 may be enhanced. Due to the enhancement of such sealing performance, adjustment and maintenance of a degree of vacuum in the interior space may become easier, and introduction of external particles may be minimized or prevented. Such a sealing member may be formed of, for example, a fluorine-based rubber, a nitrile-based rubber, or a urethane-based rubber. However, the implementations of the present disclosure are not limited thereto, and the sealing member may be formed of another material.

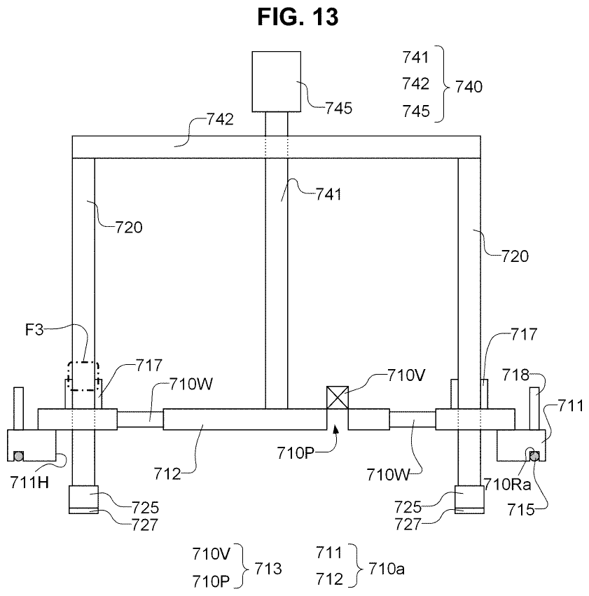

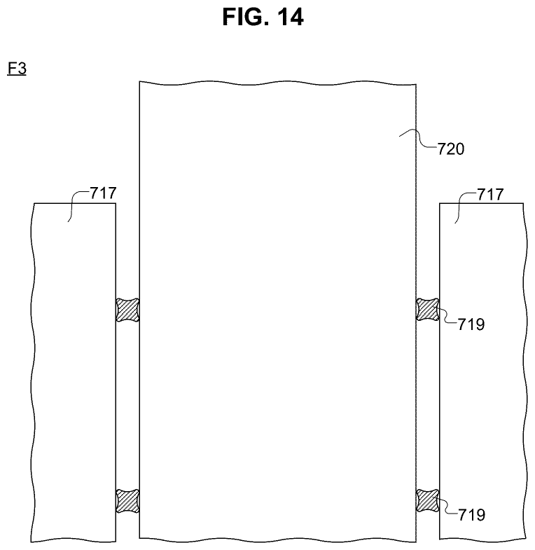

FIG. 13 is a cross-sectional view of a compression jig according to some implementations of the present disclosure. FIG. 14 is an enlarged cross-sectional view of area F3 of FIG. 13. Hereinafter, for convenience of description, the following description will focus on differences between the present implementations and the above-described implementations.

Referring to FIG. 13, a cover part 710a may include a lower cover 711 having an opening(711H) and an upper cover 712 that is provided on the lower cover 711 to cover the opening(711H). In some examples, the compression columns 720 may pass through the upper cover 712, and may pass through the opening(711H) of the lower cover 711. In some examples, a venting part 713 may be mounted on the upper cover 712. Specifically, the vent hole 710P may pass through the upper cover 712, and the opening/closing device 710V may be provided on the upper cover 712 to open and close the vent hole 710P. In some examples, a recess 710Ra may be formed within a periphery of the lower cover 711. In some examples, the first sealing member 715 may be provided in the recess 710Ra. The first sealing member 715 may be an O-ring or a D-ring. A handle 718 may be installed on an upper surface of a periphery of the lower cover 711. A plurality of handles 718 may be provided. Although not illustrated, an additional handle may be provided on the upper cover 712. In some implementations, an installation position of the handle 718 may vary. In some implementations, the handle 718 may be omitted. In some implementations, the handle 718 may also be mounted on the cover part 710 of FIG. 5. In some examples, an impact absorbing part 727 may further be provided under the compression ring 725. The impact absorbing part 727 may be coupled to a lower surface of the compression ring 725. The impact absorbing part 727 may contact an upper surface of the focus ring 21 instead of the compression ring 725. Accordingly, the impact absorbing part 727 may alleviate an impact applied to the focus ring 21 when the focus ring 21 is compressed by the compression ring 725. The impact absorbing part 727 may be formed of, for example, a sponge material having high hardness and high density. The material of the impact absorbing part 727 may be, for example, EVA foam. However, the material of the impact absorbing part 727 is not limited thereto. In some implementations, the impact absorbing part 727 may also be applied to the compression jig illustrated in FIG. 5.

Referring to FIGS. 13 and 14, in some examples, the compression jig may further include a guide part 717 and a second sealing member 719. The guide part 717 may be provided on the cover part 710a, and may surround each of the compression columns 720. When the compression columns 720 pass through the upper cover 712, the guide part 717 may be provided on the upper cover 712. The second sealing member 719 may be provided between each of the compression columns 720 and each of the guide parts 717. The second sealing member 719 may be, for example, a quad ring. However, the implementations of the present disclosure are not limited thereto. In some implementations, the second sealing member 719 may be an O-ring. A plurality of second sealing members 719 may be provided between each of the compression columns 720 and each of the guide parts 717. The second sealing members 719 between the compression columns 720 and the guide parts 717 may be disposed at different heights from each other. While the compression jig is operated on the chamber and the horizontal support 742 and the compression columns 720 are moved vertically, a sealing performance of the chamber 30 may be enhanced due to the second sealing member 719. Due to the enhancement in sealing performance, a degree of vacuum in the interior space may be maintained, and an inflow of external particles may be minimized or prevented. The quad ring, the D-ring, or the O-ring may be formed of, for example, a fluor rubber, a nitrile rubber, or a urethane rubber. However, the implementations of the present disclosure are not limited thereto, and the quad ring, the D-ring, or the O-ring may be formed of other materials.

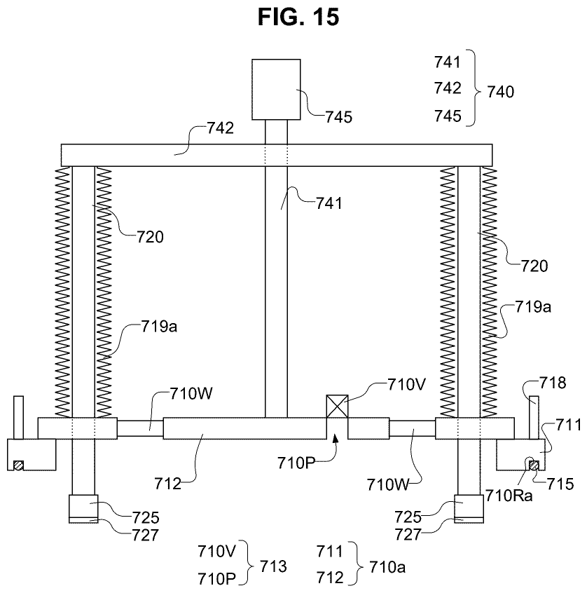

FIG. 15 is a cross-sectional view of a compression jig according to some implementations of the present disclosure. Hereinafter, for convenience of description, the following description will focus on differences between the present implementations and the above-described implementations.

Referring to FIG. 15, in some examples, a lower end of the second sealing member 719a may be connected to an upper surface of the cover part 710, and an upper end thereof may be connected to a lower surface of the horizontal support 742. Through connection of the upper end and the lower end of the second sealing member 719a, an interior space of the second sealing member 719a may be sealed. The second sealing member 719a may be installed to surround each of the compression columns 720 that are exposed on the cover part 710. The second sealing member 719a may vertically expand or vertically contract in response to vertical movement of the horizontal support 742. That is, a shape of the second sealing member 719a may be elastically deformable. Because the second sealing member 719a is deformable, sealing of an interior space of the second sealing member 719a may be maintained even when the second sealing member 719a expands or contracts along the horizontal support 742. For example, the second sealing member 719a may be a welded metal bellows. In some implementations, although not illustrated, a guide part that surrounds each of the compression columns 720 may further be provided inside the second sealing member 719a.

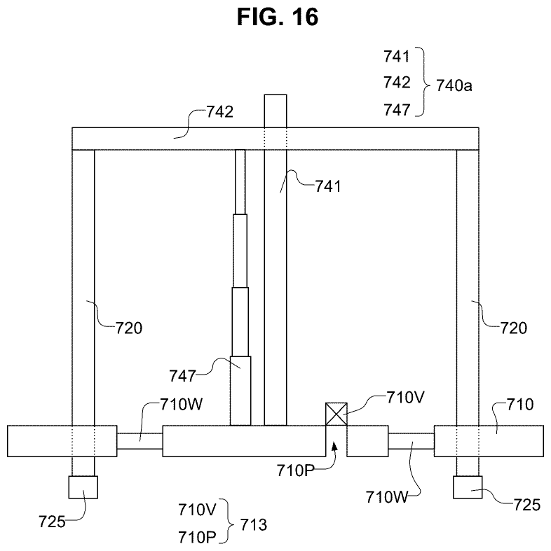

FIG. 16 is a cross-sectional view of a compression jig according to some implementations of the present disclosure. Hereinafter, for convenience of description, the following description will focus on differences between the present implementations and the above-described implementations.

Referring to FIG. 16, in the compression jig according to some implementations of the present disclosure, a mechanical driving part 740a may include the vertical support 741, the horizontal support 742, and a driver 747 for vertical movement of the horizontal support 742. The driver 747 may be connected to the horizontal support 742. In some implementations, the horizontal support 742 may be fixed to an upper end of the driver 747. The driver 747 may be provided between the horizontal support 742 and the cover part 710. When the cover part 710 includes the upper cover 712 and the lower cover 711, the driver 747 may be provided between the horizontal support 742 and the upper cover 712. The driver 747 may be vertically contractible and vertically expandable. The horizontal support 742 fixed to the upper end of the driver 747 may be vertically movable in response to contraction or expansion of the driver 747. The driver 747 may be, for example, an air cylinder that is operated by pneumatic pressure of compressed air. For example, the air cylinder may be a telescopic air cylinder. The telescopic air cylinder in FIG. 16 is illustrated as having four stages, but this is merely for convenience of description and is not limited thereto. In some implementations, a component other than a telescopic air cylinder may be used as the driver 747.

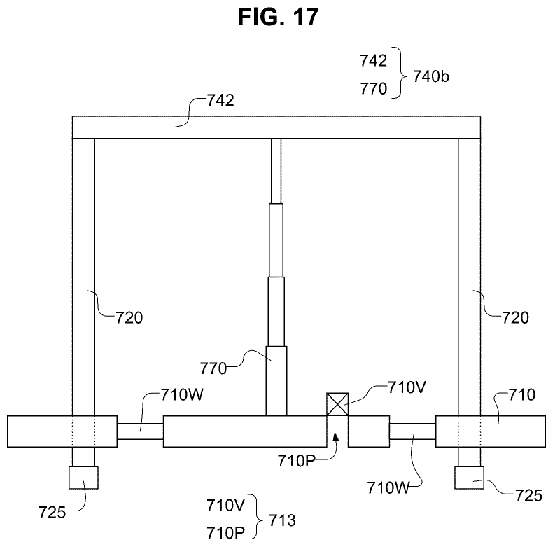

FIG. 17 is a cross-sectional view of a compression jig according to some implementations of the present disclosure. Hereinafter, for convenience of description, the following description will focus on differences between the present implementations and the above-described implementations.

Referring to FIG. 17, in the compression jig according to some implementations of the present disclosure, a mechanical driving part 740b may include a variable support 770 and a horizontal support 742. The variable support 770 may be connected to the horizontal support 742. For example, an upper end of the variable support 770 may be fixed to a lower surface of a central portion of the horizontal support 742. The variable support 770 may be provided on a central portion of an upper surface of the cover part 710. The variable support 770 may be provided on an upper surface of the cover part 710, in place of the vertical support 741 of the implementations described in FIGS. 5, 13, 15, and 16. When the cover part 710 includes the upper cover 712 and the lower cover 711, the variable support 770 may be provided between the horizontal support 742 and the upper cover 712. The compression columns 720 may be fixed to the horizontal support 742, and may be movable together with the horizontal support 742. The variable support 770 may be vertically contractible vertically and vertically expandable. The horizontal support 742 connected to the variable support 770 may be vertically movable in response to contraction or expansion of the variable support 770. The variable support 770 may be, for example, an air cylinder that is operated by pneumatic pressure of compressed air. For example, the variable support 770 may be a telescopic air cylinder. The telescopic air cylinder in FIG. 17 is illustrated as having four stages, but this is merely for convenience of description and is not limited thereto. In some implementations, a component other than a telescopic air cylinder may be used as the variable support 770.

The compression jig according to implementations of the present disclosure may compress the focus ring and the thermal pad against the chuck while the inside of the chamber is in a vacuum state. Accordingly, generation of air bubbles between the thermal pad and the chuck may be suppressed or minimized. As a result, process variation in the plasma treatment process may be reduced.

Features illustrated in the implementations may be implemented in combination with features of other implementations described above.

Although various implementations of the present disclosure have been described for illustrative purposes, those skilled in the art will appreciate that various modifications, and substitutions are possible, without departing from the scope and spirit of the present disclosure as disclosed in the accompanying claims.

Accordingly, the technical scope of the present disclosure should not be limited to the implementations described in the detailed description of the specification but should be defined by the claims.

What is claimed is:

1. A compression jig comprising:
a cover configured to cover at least a portion of a ceiling opening of a chamber;
a plurality of compression columns extending through the cover;
a compression ring being connected to a lower end of a respective compression column of the plurality of the compression columns;
a mechanical driving part on the cover and connected to the plurality of compression columns; and
a venting part defining a vent hole extending through the cover.

2. The compression jig of claim 1, wherein the chamber defines an interior space,
wherein the compression ring is configured to compress a focus ring on a periphery of a chuck in the chamber, and
wherein the cover is configured to seal the interior space in a vacuum state, based on a thermal pad being on a lower surface of the focus ring and the thermal pad being compressed by the compression ring.

3. The compression jig of claim 1, wherein the mechanical driving part comprises:
a horizontal support connected to an upper end of each of the plurality of compression columns; and
a vertical support extending through a central portion of the horizontal support, the vertical support being at a central portion of an upper surface of the cover,
wherein the horizontal support is configured to move along a lengthwise direction of the vertical support, and
wherein the plurality of compression columns are fixed to the horizontal support and are configured to move together with the horizontal support.

4. The compression jig of claim 3, wherein the mechanical driving part comprises a driver connected to an upper end of the vertical support and configured to rotate the vertical support, and
wherein the horizontal support is configured to vertically move based on a rotation of the vertical support.

5. The compression jig of claim 3, wherein the mechanical driving part comprises at least one driver between the horizontal support and the cover,
wherein the driver is configured to vertically contract and vertically expand, and
wherein the horizontal support is configured to vertically move based on a contraction or an expansion of the driver.

6. The compression jig of claim 3, wherein the horizontal support comprises a plurality of arm portions radially extending from the central portion of the horizontal support, and
wherein the upper ends of the plurality of compression columns are connected to the plurality of arm portions of the horizontal support, respectively.

7. The compression jig of claim 1, wherein the cover comprises:
a lower cover defining an opening; and
an upper cover on the lower cover and covering at least a portion of the opening,
wherein the plurality of compression columns are configured to extend through the upper cover and the opening of the lower cover, and
wherein the vent hole extends through the upper cover.

8. The compression jig of claim 1, wherein the cover defines a recess within a periphery of a lower surface of the cover, the recess extending along the periphery of the cover, and
wherein the compression jig comprises a first sealing member in the recess.

9. The compression jig of claim 1, comprising:
a plurality of guide parts on the cover, each guide part of the plurality of guide parts surrounding a respective compression column of the plurality of compression columns; and
a second sealing member between a first guide part of the plurality of guide parts and an adjacent compression column of the plurality of compression columns.

10. The compression jig of claim 1, wherein the mechanical driving part comprises:
a horizontal support connected to an upper end of each compression column of the plurality of the compression columns; and
a variable support fixed to a lower surface of a central portion of the horizontal support, the variable support being at a central portion of an upper surface of the cover,
wherein the variable support is configured to vertically contract and vertically expand,
wherein the plurality of compression columns are fixed to the horizontal support and are configured to move together with the horizontal support, and
wherein the horizontal support is configured to vertically move, based on a contraction or an expansion of the variable support.
